(19) United States
(12) Patent Application Publication
(10) Pub. No.: US 2017/0326838 A1
(43) Pub. Date: Nov. 16, 2017

(54) FIBER DELIVERY ASSEMBLY AND METHOD OF MAKING

(71) Applicant: FREE FORM FIBERS, LLC, Saratoga Springs, NY (US)

(72) Inventors: Joseph PEGNA, Saratoga Springs, NY (US); John L. SCHNEITER, Cohoes, NY (US); Kirk L. WILLIAMS, Saratoga Springs, NY (US); Ram K. GODUGUCHINTA, Ballston Lake, NY (US); Shay L. HARRISON, East Schodack, NY (US)

(73) Assignee: FREE FORM FIBERS, LLC, Saratoga Springs, NY (US)

(21) Appl. No.: 15/592,408

(22) Filed: May 11, 2017

Related U.S. Application Data
(60) Provisional application No. 62/334,622, filed on May 11, 2016.

(51) Int. Cl. B32B 7/12; B32B 5/02; B32B 37/12; C23C 16/48

(52) U.S. Cl. CPC B32B 7/12; C23C 16/483; B32B 5/02; B32B 37/12; B32B 2307/748

(57) ABSTRACT

In one aspect, a fiber delivery assembly is provided including a backing tape and a single-filament fiber coupled to the backing tape. In another aspect, a method of making a fiber delivery assembly is provided, which includes: providing a backing tape; providing a single-filament fiber; and coupling the single-filament fiber to the backing tape.

### CROSS-REFERENCE TO RELATED APPLICATION

This application claims the benefit of U.S. provisional patent application Ser. No. 62/334,622, filed May 11, 2016, entitled “Fiber Delivery Assembly and Method of Making”, which is hereby incorporated herein by reference in its entirety.

### STATEMENT REGARDING GOVERNMENT RIGHTS

Certain aspects of this invention were made with United States Government support under a U.S. Department of Energy Aware DE-SC0011954, as well as under Contract Award No. ID IIP-1152698, awarded by the National Science Foundation (NSF). Accordingly, the U.S. Government may have certain rights in this invention.

### BACKGROUND

The present invention relates generally to the field of structural fibers for reinforcing materials and more specifically to fiber reinforced composite materials and their methods of making.

In a wide variety of applications, fiber composite materials, incorporating fibers into a surrounding material matrix, provide higher performance than traditional, non-fiber reinforced materials. Conventionally, these fibers are initially delivered as twined, multi-filament fibers. Typically, however, such multi-filament fibers exhibit a significant closed porosity (i.e., fraction of pores that are inaccessible from the multi-filament fiber's surface). Thus, a fraction of the filaments internal to the multi-filament fibers are unable to couple to the surrounding material matrix, and the full promise of the fiber composite material is not realized.

### SUMMARY

In one or more aspects, a fiber delivery assembly is provided, which includes: a backing tape; and a single-filament fiber coupled to the backing tape.

In one or more other aspects, a method of making a fiber delivery assembly is provided, which comprises: providing a backing tape; providing a single-filament fiber; and coupling the single-filament fiber to the backing tape.

Additional features and advantages are realized through the techniques of the present invention. Other embodiments and aspects of the invention are described in detail herein and are considered a part of the claimed invention.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a schematic representation of a single-fiber reactor, showing a seed fiber substrate, a reactor cube into which precursor gases are delivered, a focused laser beam impinging on the seed fiber, and reactor windows that are transparent to the incoming laser beam wavelength and allow for video monitoring of the process;

FIG. 2 is a schematic view showing how fiber LCVD can be massively parallelized by multiplication of the laser beams;

FIG. 3 is an example of parallel LCVD growth of carbon fibers;

FIG. 4 illustrates an isometric view of one embodiment of a fiber delivery assembly, in accordance with one or more aspects of the present invention; and

FIG. 5 illustrates an isometric view of another embodiment of a fiber delivery assembly, in accordance with one or more aspects of the present invention.

### DETAILED DESCRIPTION

Aspects of the present invention and certain features, advantages and details thereof, are explained more fully below with reference to the non-limiting example(s) illustrated in the accompanying drawings. Descriptions of well-known systems, devices, fabrication and processing techniques, etc., are omitted so as to not unnecessarily obscure the invention in detail. It should be understood, however, that the detailed description and the specific example(s), while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure. Note further that numerous inventive aspects and features are disclosed herein, and unless inconsistent, each disclosed aspect or feature is combinable with any other disclosed aspect or feature as desired for a particular application, for instance, for facilitating providing fiber delivery assemblies and methods of making, as described herein.

The present invention relates generally to the field of structural fibers for reinforcing materials and more specifically to the field of assemblies for delivering such fibers.

Fiber-reinforced composite materials are designed to concomitantly maximize strength and minimize weight. This is achieved by embedding high-strength low-density fibers into a low-density filler matrix in such a way that fibers channel and carry the structural stresses in composite. The matrix serves as a glue that holds fibers together and helps transfer loads in shear from fiber to fiber, but in fact the matrix material is not a structural element and carries but a negligible fraction of the overall structural load seen by a composite material. Hence any part of the matrix material that does not contain fibers is essentially parasitic weight that does not contribute to the structural load carrying function of a composite structure. In essence, space that is filled with matrix but does not contain fibers is wasted space for structural purposes.

The goal of composite material fabrication, therefore, should be to maximize the amount of fiber contained in an arbitrary volume contained within the composite structure, which is referred to as “fiber volume fraction”.

In practice, fiber volume fraction typically measures the overall fraction of the composite's volume occupied by fibers. In the spirit that any of the composite's volume not containing fibers is wasted, however, fiber volume fraction should be uniform throughout the composite, at least within a scale no larger than one order of magnitude greater than the fiber diameter.

The objective of composite manufacturing must therefore be to pack as much fiber as uniformly as possible throughout the composite volume. Such an effort, however, is bound by physical limits dictated by circular packing. If we assume all the fibers running parallel to each other and having uniform diameter, then the ultimate fiber volume fraction is bound by the hexagonal circular packing fraction of 4π/9\sqrt{3}, or 80%. In practice, however, fibers are usually arranged in overlaid cross-plies, which limits the volume fraction to the square packing of circles π/4, or 78.5%. With such high packing fractions, each fiber would be in contact along lines with six neighbors around its perimeter in the case of hexagonal packing, or in line contact with two neighbors and point contact with two others in the case of square packing overlay. Beside the real potential of causing mechanical damage, such extensive fiber-to-fiber contact would also make infiltration of a matrix extremely challenging. For these reasons, the maximum theoretical fiber volume fractions are undesirable, and one would want to have enough fiber-to-fiber separation as to provide some mechanical protection to the fibers while also easing manufacturing.

So, while it would appear that one would want to produce composite material near, but not at, the theoretical upper volume fraction limit, composites produced in practice often exhibit fiber volume fractions that sway far in the opposite direction, usually around half the upper limit and often less. Beside economic reasons, since fibers tend to be significantly more expensive than matrix, there are rigid constraints deeply rooted in the notion of fiber, its geometry, its topology, and its mechanics. We begin by clarifying our notion of fiber.

Fibers are an ancient concept, documented at least 7000 years ago in ancient Chinese archaeological artifacts. Such ancient roots mean that the semantics for “fiber” has been expanded greatly through the century, even to the point of acquiring many metaphorical meanings (e.g.: “Fiber of one's being”). To steer clear of potential ambiguities in the discussion that follows, we first need to clarify our terminology.

In the textile industry, and by extension in the composite fiber industry (e.g. glass, carbon, or silicon carbide fibers) what is traditionally called fibers is in fact an assembly of entangled filaments or fibrils. A filament is usually reserved for synthetic materials whereas fibrils are used to describe biological products. In both instances, the filament (or fibril) is the smallest continuous constituent that can be teased out of the fiber without break in material continuity. In other words, the filament or fibril is the fundamental constituent of a fiber. Filaments or fibrils are highly elongated solid material with axial dimensions many orders of magnitude larger than their characteristic cross-sectional dimensions, which endows them with the high flexibility necessary for entanglement into a fiber assembly. So while the filaments or fibrils are of finite lengths, they can be assembled (and often twisted) into objects of apparent indefinite length, which are referred to by different names depending on the field of application, e.g., fibers, threads, tows, yarn, etc. A cotton thread, for example, is not a single monolithic material, it is made of the assembly of a large numbers of small, thin cotton fibrils twisted and entangled together through a process called “ginning” or “spinning”. The same can be said of silk thread or wool yarn, which are just assemblies into a seemingly continuous fiber. All of the aforementioned fibers are man-made; they are explicitly assembled from raw vegetal, animal, or synthetic filaments or fibrils. Furthermore, large numbers of fibers can be further organized into twisted assemblies that will yield cords or ropes depending again of the field of application. Language ambiguity applies to large assemblies of filaments, but it also extends to a filament count of one. For example, in the field of optics, a single continuous glass filament is called an optical fiber. Similarly, single continuous metallic filaments—called wires—can be twisted into cables. Hence, for the purpose of clarity in this presentation, we refer to a “monofilament” as a continuous inorganic filament, as opposed to assemblies thereof.

The fact that a typical fiber (or yarn or tow depending on the field of application) is a randomly packed assembly of filaments necessarily reduces the fiber volume fraction within the tow. When subsequently braided or woven, tows are now arranged in low-density packing that further reduces the fiber volume fraction to the levels commonly seen in composite structures.

It should be noted as well that braiding or weaving is known to damage fibers and causes a residual level of stresses in the fibers that take a significant toll on strength. Practitioners of composite materials have taken notice. Some have started working with untangled tows that lay filaments into a flat pattern reminiscent of ribbons and are subsequently overlaid as a series of pre-impregnated tows. No loss of strength, and even improvements, have been reported as a result of substituting woven fabric with untangled and flatten unidirectional tows.

While flatten tows show an improvement over the state of the art, the resulting ribbons still inherit a random arrangement of the constitutive filaments, that cross over each other, holding fiber volume fraction down and yield necessarily uneven tow thickness.

Ultimately, if one were to achieve maximum fiber volume fraction, one would need well-ordered arrays of monofilaments, evenly spaced, and only one filament thick.

Such architecture can be obtained directly by modern fiber laser printing approaches such as described by Pegna et al., U.S. Patent Publication No. 2015/0004393 A1, which is hereby incorporated herein by reference in its entirety.

Such monolayer of monofilament architecture not only maximize fiber volume fraction in a composite, but when overlaid along different directions, they leave an open porosity network that facilitates matrix infiltration, thus improving the quality of the composites. This feature addresses a weakness of current infiltration processes that often cannot reach into intra-tow or inter-weave closed porosities, hence resulting in a locally weakened composite.

Opportunities exist, therefore, to improve fiber-to-matrix coupling by providing a fiber delivery system for delivering fibers as single-filament fibers.

The opportunities described above are addressed, in one embodiment of a first aspect of the present invention, by a fiber delivery assembly comprising a backing tape and a single-filament fiber coupled to the backing tape. In an embodiment of a second aspect of the present invention, a method of making a fiber delivery assembly comprises acts of providing a backing tape, providing a single-filament fiber, and coupling the single-filament fiber to the backing tape.

Disclosed herein, in part, is the concept of avoiding the use of polymeric precursors altogether by using laser-assisted chemical vapor deposition (LCVD) as is described in U.S. Pat. No. 5,786,023 by Maxwell and Pegna, the entirety of which is hereby incorporated by reference herein. In this process pure precursor gases (such as silane and ethylene in the case of SiC fiber production) are introduced into a reactor within which a suitable substrate such as glassy carbon is positioned, and laser light is focused onto the substrate. The heat generated by the focused laser beam breaks down the precursor gases locally, and the atomic species deposit onto the substrate surface and build up locally to form a fiber. If either the laser or the substrate is pulled away from this growth zone at the growth rate a continuous fiber filament will be produced with the very high purity of the starting gases. With this technique there are virtually no unwanted impurities, and in particular no performance-robbing oxygen.

Very pure fibers can be produced using LCVD, such as silicon carbide, boron carbide, silicon nitride and others. The inventors have discovered that if a material has been deposited using CVD, there is a good chance that fiber can be produced using LCVD. Unlike with liquid polymeric precursors, however, where the chemistry can be very involved and complicated even for relatively ‘simple’ materials such as those mentioned above, LCVD can also be used quite directly to produce novel mixes of solid phases of different materials that either cannot be made or have not been attempted using polymeric precursor and spinneret technology. Examples include fibers composed of silicon, carbon and nitrogen contributed by the precursor gases such as silane, ethylene and ammonia, respectively, where the resulting “composite” fiber contains tightly integrated phases of silicon carbide, silicon nitride and silicon carbonitrides depending on the relative concentrations of precursor gases in the reactor. Such new and unique fibers can exhibit very useful properties such as high temperature resistance, high strength and good creep resistance at low relative cost.

Disclosed below is a novel multi-component or ‘composite’ inorganic fiber comprising a nano-scale contiguous collection of a number of tightly packed unique phases of material randomly interspersed throughout the fiber body, without unwanted impurities, and a method for producing same.

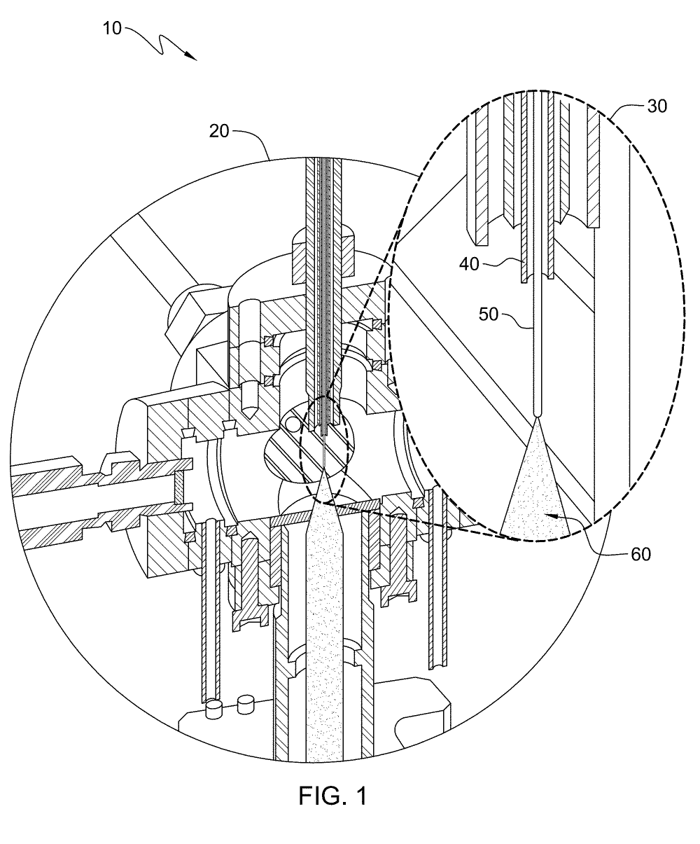

FIG. 1 shows a LCVD reactor into which a substrate seed fiber has been introduced, onto the tip of which a laser beam is focused. (It will be seen that the substrate may be any solid surface capable of being heated by the laser beam. It will further be seen that multiple lasers could be used simultaneously to produce multiple simultaneous fibers as is taught in International Patent Application Serial No. US2013/022053 by Pegna et al.,—also filed on Jul. 14, 2014 as U.S. patent application entitled “High Strength Ceramic Fibers and Methods of Fabrication”, U.S. Ser. No. 14/372,085—the entireties of which are hereby incorporated by reference herein.) In accordance with that application, FIG. 1 more particularly shows a reactor 10; enlarged cutout view of reactor chamber 20; enlarged view of growth region 30. A self-seeded fiber 50 grows towards an oncoming coaxial laser 60 and is extracted through an extrusion microtube 40.

A mixture of precursor gases can be introduced at a desired relative partial pressure ratio and total pressure. The laser is turned on, generating a hot spot on the substrate, causing local precursor breakdown and local CVD growth in the direction of the temperature gradient, typically along the axis of the laser beam. Material will deposit and a fiber will grow, and if the fiber is withdrawn at the growth rate, the hot spot will remain largely stationary and the process can continue indefinitely, resulting in an arbitrarily long CVD-produced fiber.

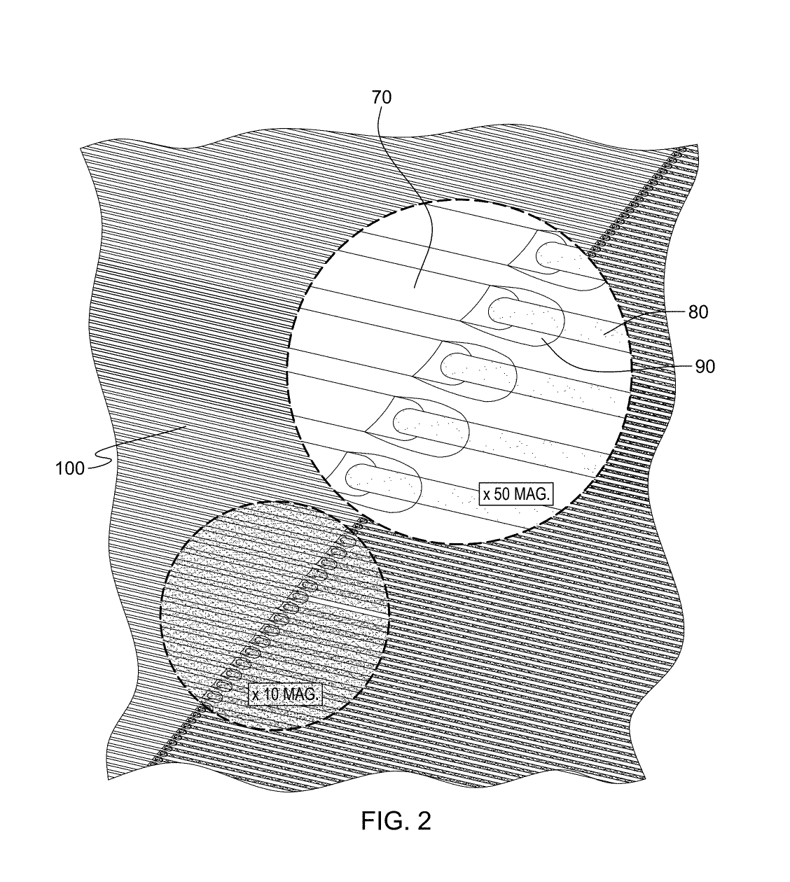

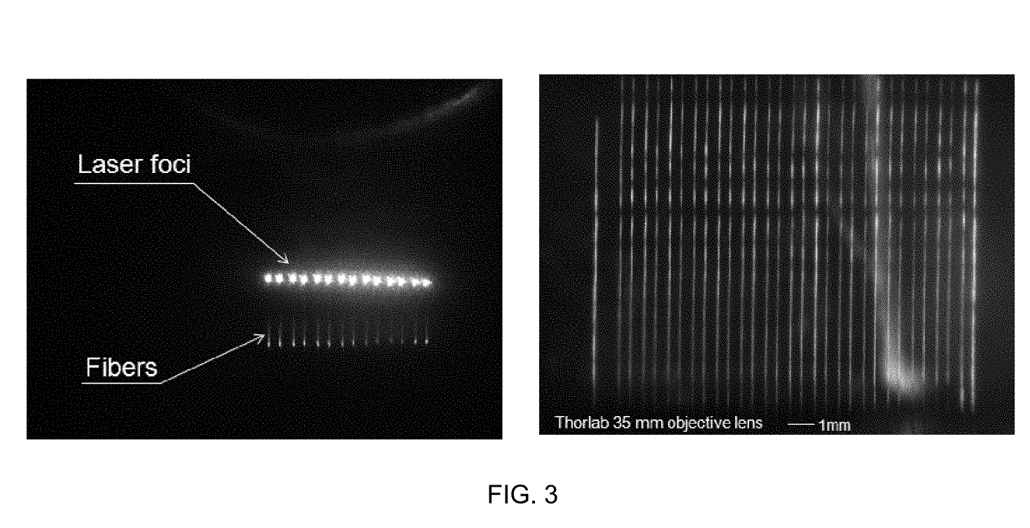

Also in accordance with that Application, a large array of independently controlled lasers can be provided, growing an equally large array of fibers 80 in parallel, as illustrated in FIG. 2, showing how fiber LCVD can be massively parallelized from a filament lattice 100 by multiplication of the laser beams 80 inducing a plasma 90 around the tip of each fiber 70. Using a CtP (e.g., QWI) laser array for LCVD is a scientific first, and so was the use of a shallow depth of focus. It provides very beneficial results. Sample carbon fibers, such as those shown in FIG. 3, were grown in parallel. FIG. 3 shows parallel LCVD growth of carbon fibers—Left: Fibers during growth and Right: Resulting free standing fibers 10-12 μm in diameter and about 5 mm long.

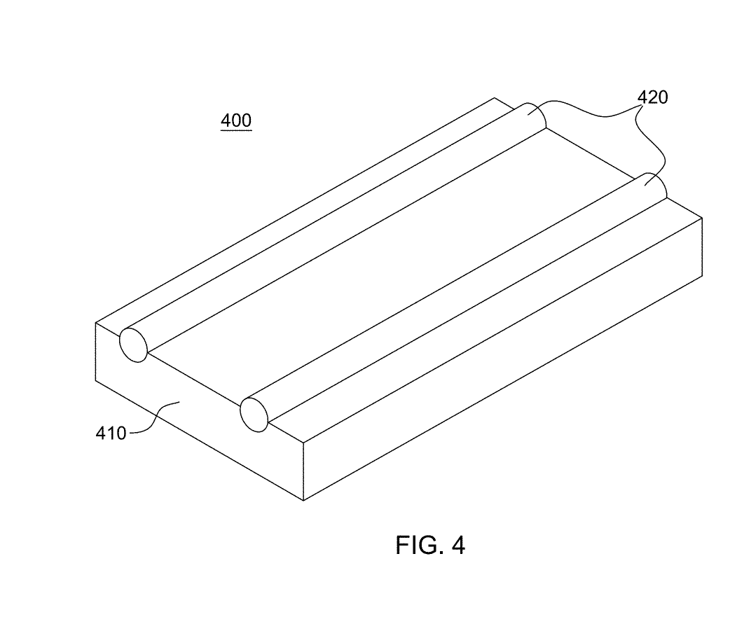

FIG. 4 illustrates an isometric view of a portion of one embodiment of a fiber delivery assembly 400, in accordance with one or more aspects of the present invention. In the embodiment shown, fiber delivery assembly 400 comprises a backing tape 410 and a single-filament fiber 420 coupled to backing tape 410, such as being directly adhered to backing tape 410. In one or more implementations, fiber delivery assembly 400 may be of any desired length. Further, note that in one or more embodiments, any number of single-filament fibers 420 may be coupled to backing tape 410 including, for instance, 1, 2, 3, 4, . . . n, where ‘n’ is any integer number which may be accommodated by the width of backing tape 410.

In one or more implementations, backing tape 410 may comprise a polymer material (such as, for instance, a thermoplastic thermoset or pre-ceramic polymer material), and single-filament fiber 420 may be coupled to backing tape 410 by being embedded in backing tape 410. Such embodiments facilitate the fabrication of polymer matrix composite materials in that backing tape 410 provides the material matrix.

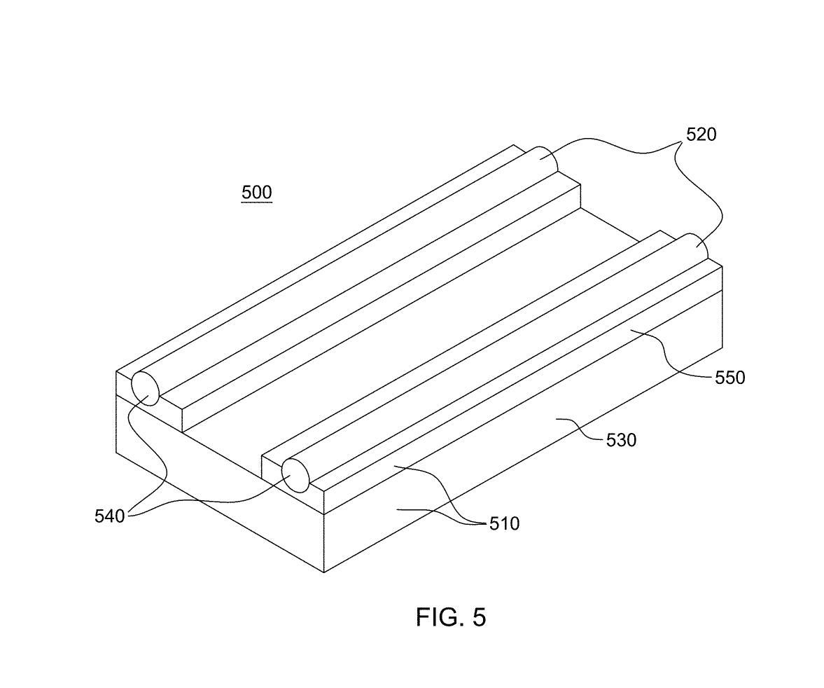

In accordance with one or more other embodiments, FIG. 5 illustrates an isometric drawing of a fiber delivery assembly 500 wherein backing tape 510 comprises a backing tape substrate 530 and an adhesive layer 540 disposed between, and adhering to, backing tape substrate 530 and single-filament fiber 520. Note that in one or more implementations, a separate adhesive layer 540 may be provided for each single-filament fiber 520, as in the embodiment illustrated in FIG. 5.

In one or more implementations of the fiber delivery assembly of FIG. 5, adhesive layer 540 may comprise a heat-release or dissolvable adhesive. During the process of laying up single-filament fiber 520 to form an engineering part (for example, by winding single-filament fiber 520 on a mandrel), heat applied to the heat-release adhesive allows backing tape substrate 530 to fall away and be excluded from the final fiber composite material.

In one or more further aspects of the present invention, a method of making fiber delivery assembly 400 FIG. 4 (or fiber delivery assembly 500 of FIG. 5) is provided, which includes providing a backing tape 410 (510), providing a single-filament fiber 420 (520), and coupling single-filament fiber 420 (520) to backing tape 410 (510).

In one or more aspects of the present invention, backing tape 410 (510) may comprise a polymer material, and the coupling of single-filament fiber 420 (520) to backing tape 410 (510) may include embedding single-filament fiber 420 (520) in backing tape 410 (510).

In one or more further embodiments, the providing of backing tape 510 may comprise providing a backing tape substrate 530 and disposing an adhesive layer 540 between backing tape substrate 530 and single-filament fiber 520. Furthermore, the coupling of single-filament fiber 520 to backing tape 510 may include adhering single-filament fiber 520 and backing tape substrate 530 to adhesive layer 540. In certain embodiments, adhesive layer 540 may comprise a heat-release adhesive 550.

In one or more embodiments of the present invention, the providing of a single-filament fiber 420 (520) may comprise growing single-filament fiber 420 (520) using laser-assisted chemical vapor deposition.

In one or more implementations, the single-filament fiber may comprise a solid material, or ordinarily solid material, selected from a group consisting of boron, carbon, aluminum, silicon, titanium, zirconium, niobium, molybdenum, hafnium, tantalum, tungsten, rhenium, osmium, nitrogen, oxygen, and combinations thereof. As used herein, an “ordinarily solid material” means a material that is solid at a temperature of 20° C., and a pressure of 1 atmosphere.

Note further that in one or more implementations, the single-filament fiber 120 (220) has a substantially non-uniform diameter (now shown). This non-uniformity of diameter facilitates or aids in coupling the fiber to the surrounding material.

Note also, in one or more embodiments, the fibers, or one or more portions of the fibers, disclosed herein may be fabricated using (alone or in any combination) one or more of the techniques described in PCT Application No. PCT/US2013/22053, entitled “High Strength Ceramic Fibers and Methods of Fabrication”, which published on Dec. 5, 2013, as PCT Publication No. WO 2013/180764 A1, and in PCT Application No. PCT/US2015/037080, entitled “An Additive Manufacturing Technology for the Fabrication and Characterization of Nuclear Reactor Fuel”, which published on Dec. 30, 2015, as PCT Publication No. WO 2015/200257 A1, both of which are hereby incorporated by reference in their entirety.

Those skilled in the art will note from the above description that provided herein is a fiber delivery assembly which includes, for instance, a backing tape, and a single-filament fiber coupled to the backing tape. In one or more implementations, the backing tape may include a polymer material, and the single-filament fiber may be coupled to the backing tape by being embedded in the backing tape. In one or more embodiments, the backing tape may include a backing tape substrate, and an adhesive layer may be disposed between and adhering to the backing tape substrate and the single-filament fiber. In particular, the adhesive layer may include a heat-release adhesive. The single-filament fiber may include an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof. Further, the single-filament fiber may have a substantially non-uniform diameter.

In one or more other aspects, a fiber deliver assembly is provided which includes a backing tape substrate, a single-filament fiber, and an adhesive layer disposed between and adhering to the backing tape substrate and the single-filament fiber. The single-filament fiber includes an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof. Further, the single-filament fiber may have a substantially non-uniform diameter and/or the adhesive layer may include a heat-release adhesive.

In one or more other aspects, a method of making a fiber delivery assembly is provided which includes providing a backing tape, providing a single-filament fiber, and coupling the single-filament fiber to the backing tape. In one or more implementations, the backing tape includes a polymer material, and the coupling of the single-filament fiber to the backing tape includes embedding the single-filament fiber in the backing tape. In one or more embodiments, providing the backing tape may include providing a backing tape substrate, and disposing an adhesive layer between the backing tape substrate and the single-filament fiber. The coupling of the single-filament fiber to the backing tape may include adhering the single-filament fiber and the backing tape substrate to the adhesive layer. The adhesive layer may include a heat-release adhesive. In one or more embodiments, the single-filament fiber includes an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof. Further, the single-filament fiber may have a substantially non-uniform diameter. Also, the providing of a single-filament fiber may include growing the single-filament fiber using laser-assisted chemical vapor deposition.

In one or more further aspects, a method of making a fiber delivery assembly is provided which includes: providing a backing tape substrate; growing a single-filament fiber using laser-assisted chemical vapor deposition; disposing an adhesive layer between the backing tape substrate and the single-filament fiber; and adhering the adhesive layer to the backing tape substrate and the single-filament fiber. In one or more embodiments, the single-filament fiber includes an ordinarily solid material selected from a group consisting of boron, carbon, aluminum, silicon, titanium, zirconium, niobium, molybdenum, hafnium, tantalum, tungsten, rhenium, osmium, nitrogen, oxygen, and combinations thereof. Further, the single-filament fiber may have a substantially non-uniform diameter, and the adhesive layer may include a heat-release adhesive.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A fiber delivery assembly comprising:
a backing tape; and
a single-filament fiber coupled to the backing tape.

2. The fiber delivery assembly of claim 1, wherein:
the backing tape comprises a polymer material; and
the single-filament fiber is coupled to the backing tape by being embedded in the backing tape.

3. The fiber delivery assembly of claim 1, wherein the backing tape comprises:
a backing tape substrate; and
an adhesive layer disposed between and adhering to the backing tape substrate and said single-filament fiber.

4. The fiber delivery assembly of claim 3, wherein the adhesive layer comprises a heat-release adhesive.

5. The fiber delivery assembly of claim 1, wherein the single-filament fiber comprises a solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

6. The fiber delivery assembly of claim 1, wherein the single-filament fiber is directly adhered to the backing tape.

7. The fiber delivery assembly of claim 1, wherein the single-filament fiber is releasably coupled to the backing tape.

8. The fiber delivery assembly of claim 1, wherein the single-filament fiber has a substantially non-uniform diameter.

9. A fiber delivery assembly comprising:
a backing tape substrate;
a single-filament fiber; and
an adhesive layer disposed between and adhering to the backing tape substrate and the single-filament fiber,
the single-filament fiber comprising a solid material selected from a group consisting of boron, carbon, aluminum, silicon, titanium, zirconium, niobium, molybdenum, hafnium, tantalum, tungsten, rhenium, osmium, nitrogen, oxygen, and combinations thereof.

10. The fiber delivery assembly of claim 9, wherein the adhesive layer comprises a heat-release adhesive.

11. The fiber delivery assembly of claim 9, wherein the adhesive layer is releasably attached to the backing tape substrate, the single-filament fiber remaining coupled to the adhesive layer with releasing of the adhesive layer from the backing tape substrate.

12. A method of making a fiber delivery assembly, the method comprising:
providing a backing tape;
providing a single-filament fiber; and
coupling the single-filament fiber to the backing tape.

13. The method of claim 12, wherein:
the backing tape comprises a polymer material; and
the coupling of the single-filament fiber to the backing tape comprises embedding the single-filament fiber in the backing tape.

14. The method of claim 12, wherein:
the providing the backing tape comprises
providing a backing tape substrate;
disposing an adhesive layer between the backing tape substrate and the single-filament fiber; and
the coupling of the single-filament fiber to the backing tape comprises adhering the single-filament fiber and the backing tape substrate to the adhesive layer.

15. The method of claim 14, wherein the adhesive layer comprises a heat-release adhesive.

16. The method of claim 12, wherein the single-filament fiber comprises a material selected from a group consisting of carbon, boron, silicon carbide, and boron nitride.

17. The method of claim 12, wherein the providing a single-filament fiber comprises growing the single-filament fiber using laser-assisted chemical vapor deposition.

18. A method of making a fiber delivery assembly comprising:
providing a backing tape substrate;
growing a single-filament fiber using laser-assisted chemical vapor deposition;
disposing an adhesive layer between the backing tape substrate and the single-filament fiber; and
adhering the adhesive layer to the backing tape substrate and the single-filament fiber.

19. The method of claim 18, wherein the single-filament fiber comprises a material selected from a group consisting of carbon, boron, silicon carbide, and boron nitride.

20. The method of claim 18, wherein the adhesive layer comprises a heat-release adhesive.
